(19) United States
(12) Patent Application Publication
(10) Pub. No.: US 2024/0074113 A1
(43) Pub. Date: Feb. 29, 2024

(54) AEROGEL HEAT EXTRACTION APPARATUS FOR DATA CENTERS AND ENERGY STORAGE SYSTEMS

(71) Applicant: roVa Corporation, Seoul (KR)

(72) Inventors: Jason KIM, Seoul (KR); Choonsoo HAHN, Seoul (KR)

(21) Appl. No.: 17/899,454

(22) Filed: Aug. 30, 2022

(51) Int. Cl. H05K 7/20

(52) U.S. Cl. CPC H05K 7/2039; H05K 7/20709

(57) ABSTRACT

A device includes an enclosure for one or more electronic devices. The enclosure includes an insulation layer that includes aerogels and binder. The insulation layer may have a thermal conductivity of less than 30 mW/m·K at 25° C.

### RELATED APPLICATIONS

This application is related to U.S. patent application Ser. No. ______, filed concurrently herewith, entitled “Aerogel Heat Extraction Sheets, Cables, and Apparatus,” (Attorney Docket Number 130807-5001-US), which is incorporated by reference herein in its entirety.

### TECHNICAL FIELD

The disclosed embodiments relate generally to aerogels and in particular to heat transfer devices that include aerogels.

### BACKGROUND

Thermal management plays an important role in operation of electronic devices. Several electrical or electronic components generate heat during operation, and excessive heat can impair the performance of electronic devices, including reduced reliability and premature failure.

Conventionally, heat transfer devices, such as heat sinks and heat pipes, have been used to transfer heat generated by electrical or electronic components.

### SUMMARY

Conventional heat transfer devices release heat in locations that are not desirable for dissipating heat. For example, conventional heat transfer devices may form thermal hotspots, which may reduce the overall performance of electronic devices and may cause other undesirable outcomes (e.g., overheating of the electronic devices in locations that may be contacted by a user).

Accordingly, there is a need for heat transfer devices with the ability to select locations of heat dissipation. Such heat transfer devices are particularly desirable for computers, energy storage systems, or data centers, where a large amount of heat is generated by electrical or electronic components.

Aerogels, and in particular silica aerogels, exhibit low thermal conductivity making them useful as insulative materials. Aerogels can be used to reduce thermal hotspots or combined with high thermal conductivity materials to form a heat extraction tunnel without affecting the ambient atmosphere, and therefore, the ambient temperature. Such materials can be useful in reducing hotspot temperatures and cooling components in computers, electronics, energy storage systems (ESS), and data centers.

In accordance with some embodiments, a device includes an enclosure for one or more electronic devices. The enclosure includes an insulation layer that includes aerogels and binder. This allows transfer of heat to locations that reduce the thermal effect on electrical or electronic components and are better suited for heat extraction.

The above deficiencies and other problems associated with conventional heat transfer devices are reduced or eliminated by the devices disclosed herein. Various embodiments within the scope of the appended claims each have several aspects, no single one of which is solely responsible for the attributes describe herein. Without limiting the scope of the appended claims, after considering this disclosure, and particularly after considering the section entitled “Detailed Description,” one will understand how the aspects of various embodiments are used to provide improved heat transfer devices.

### BRIEF DESCRIPTION OF THE DRAWINGS

In order that the present disclosure can be understood in greater detail, a more particular description is made in reference to the features of various embodiments, some of which are illustrated in the appended drawings. The appended drawings, however, merely illustrate the more pertinent features of the present disclosure and are therefore not to be considered limiting, for the description may admit to other effective features.

FIGS. 1-7 illustrate heat transfer devices in accordance with some embodiments.

FIGS. 8-10 are exploded views showing components of devices with enclosures in accordance with some embodiments.

FIG. 11 illustrates a rack in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Reference will now be made in detail to embodiments, examples of which are illustrated in the accompanying drawings. In the following detailed description, numerous non-limiting specific details are set forth to assist in understanding the subject matter presented herein. It will be apparent, however, to one of ordinary skill in the art that various alternatives may be used without departing from the scope of the claims, and that the subject matter may be practiced without these specific details. In other instances, well-known methods, procedures, components, circuits, and systems have not been described in detail so as not to unnecessarily obscure aspects of the embodiments. In addition, features described with respect to particular embodiments, may be combined with features described with respect to other embodiments without limitation, unless explicitly stated otherwise.

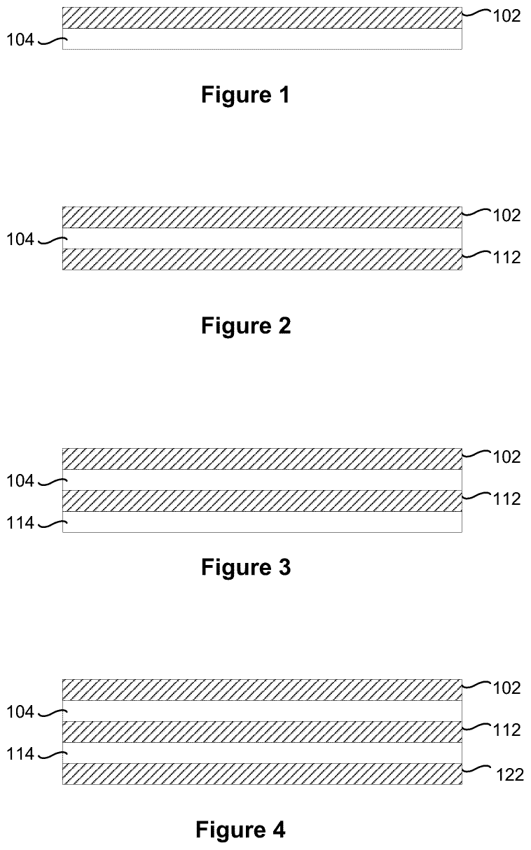

FIG. 1 illustrates a heat transfer device in accordance with some embodiments.

The device includes a first insulation layer 102 that comprises aerogels and binder.

As described above, the aerogels have low thermal conductivity. In some embodiments, the first insulation layer has a thermal conductivity of less than 30 mW/m·K at 25° C.

The first insulation layer may be characterized by its length, width, and height. The first insulation layer has the length and the width, which are greater than its height. In some embodiments, the length and the width are at least 10, 20, 30, 40, 50, 60, 70, 80, 90, or 100 times greater than the height.

In some embodiments, the first insulation layer has a shape of a sheet. For example, in some configurations, the length and the width are substantially the same. In some configurations, the length is not greater than 2, 3, 4, or 5 times the width. In some configurations, the width is not greater than 2, 3, 4, or 5 times the length.

In some embodiments, the first insulation layer has a shape of a strip. For example, in some configurations, the length is substantially greater than the width (or the width is substantially greater than the length). In some configurations, the length is greater than 5, 6, 7, 8, 9, 10, 15, or 20 times the width. In some configurations, the width is greater than 5, 6, 7, 8, 9, 10, 15, or 20 times the length.

In some embodiments, the device also includes a first thermally conductive layer 104.

In some embodiments, the first thermally conductive layer is in contact with the first insulation layer, as shown in FIG. 1. In some embodiments, the first thermally conductive layer is not in contact with the first insulation layer (e.g., an adhesive layer may be located between the first thermally conductive layer and the first insulation layer).

The first thermally conductive layer may be characterized by its length, width, and height. The first thermally conductive layer has the length and the width, which are greater than its height. In some embodiments, the length and the width are at least 10, 20, 30, 40, 50, 60, 70, 80, 90, or 100 times greater than the height.

In some embodiments, the first thermally conductive layer has a shape of a sheet. For example, in some configurations, the length and the width are substantially the same. In some configurations, the length is not greater than 2, 3, 4, or 5 times the width. In some configurations, the width is not greater than 2, 3, 4, or 5 times the length.

In some embodiments, the first thermally conductive layer has a shape of a strip. For example, in some configurations, the length is substantially greater than the width (or the width is substantially greater than the length). In some configurations, the length is greater than 5, 6, 7, 8, 9, 10, 15, or 20 times the width. In some configurations, the width is greater than 5, 6, 7, 8, 9, 10, 15, or 20 times the length.

In some embodiments, the first thermally conductive layer has the same shape as the first insulation layer. In some embodiments, the first thermally conductive layer has a shape distinct from the shape of the first insulation layer.

In some embodiments, the first thermally conductive layer includes one or more of: graphite, pyrolytic graphite, aluminum, or copper. In some embodiments, any thermally conductive layer described herein includes one or more of: graphite, pyrolytic graphite, aluminum, or copper.

FIG. 2 illustrates a heat transfer device in accordance with some embodiments. The device shown in FIG. 2 is similar to the device shown in FIG. 1, except that the device shown in FIG. 2 includes a second insulation layer 112 that includes aerogels and binder. The first thermally conductive layer is located between the first insulation layer and the second insulation layer.

In some embodiments, the second insulation layer 112 has the same thermal conductivity as that of the first insulation layer 102 (e.g., the second insulation layer 112 has the same composition of aerogels and binders as that of the first insulation layer 102). In some embodiments, the second insulation layer 112 and the first insulation layer 102 have different thermal conductivities (e.g., the second insulation layer 112 has a composition of aerogels and binders different from that of the first insulation layer 102).

In some embodiments, the second insulation layer 112 is in contact with the first thermally conductive layer. In some embodiments, the second insulation layer 112 is not in contact with the first thermally conductive layer (e.g., an adhesive layer may be located between the second insulation layer and the first thermally conductive layer).

FIG. 3 illustrates a heat transfer device in accordance with some embodiments. The device shown in FIG. 3 is similar to the device shown in FIG. 2, except that the device shown in FIG. 3 includes a second thermally conductive layer 114. The second insulation layer 112 is located between the first thermally conductive layer 104 and the second thermally conductive layer 114.

In some embodiments, the second thermally conductive layer 114 is in contact with the second insulation layer 112. In some embodiments, the second thermally conductive layer 114 is not in contact with the second insulation layer 112.

FIG. 4 illustrates a heat transfer device in accordance with some embodiments. The device shown in FIG. 4 is similar to the device shown in FIG. 3, except that the device shown in FIG. 4 includes a third insulation layer 122 that includes aerogels and binder. The second thermally conductive layer 114 is located between the second insulation layer 112 and the third insulation layer 122.

In some embodiments, the third insulation layer 122 is in contact with the second thermally conductive layer 114. In some embodiments, the third insulation layer 122 is not in contact with the second thermally conductive layer 114.

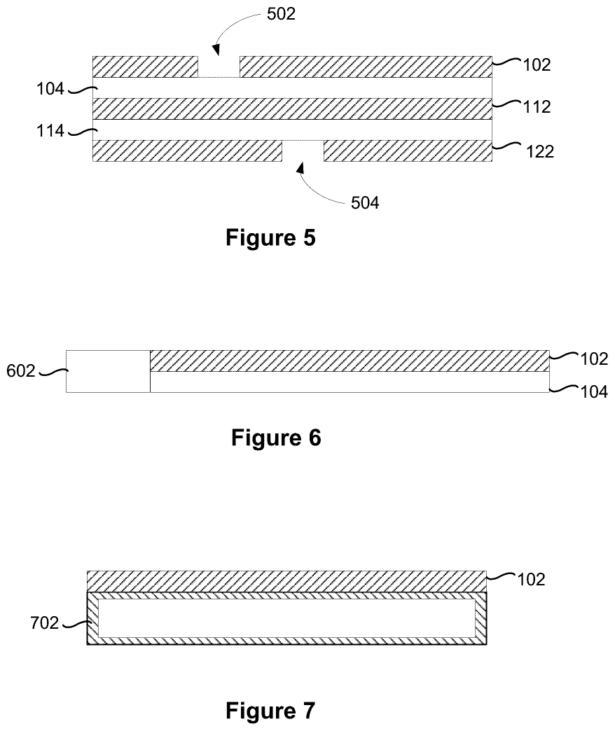

FIG. 5 illustrates a heat transfer device in accordance with some embodiments. The device shown in FIG. 5 is similar to the device shown in FIG. 4, except that in the device shown in FIG. 5, the first insulation layer 102 defines a first set of one or more through-holes 502 for allowing a first set of one or more thermal vias to couple with the first thermally conductive layer and the third insulation layer 122 defines a second set of one or more through-holes 504 for allowing a second set of one or more thermal vias to couple with the second thermally conductive layer.

In some embodiments, the first thermally conductive layer 104 and the second thermally conductive layer 114 form multiple heat extraction paths (e.g., FIGS. 3, 4, and 5).

FIG. 6 illustrates a heat transfer device in accordance with some embodiments. The device shown in FIG. 6 is similar to the device shown in FIG. 1, except that the device shown in FIG. 6 includes a thermally conductive block 602 thermally coupled with the first thermally conductive layer 104. The thermally conductive block 602 may be characterized by its length, width, and height. In some embodiments, the height of the thermally conductive block 602 is greater than the height of the first thermally conductive layer 104. In some embodiments, the length of the thermally conductive block 602 is greater than the length of the first thermally conductive layer 104. In some embodiments, the width of the thermally conductive block 602 is greater than the width of the first thermally conductive layer 104. In some embodiments, the thermally conductive block 602 includes thermally conductive material, such as aluminum or copper. In some embodiments, the thermally conductive block 602 consists of one or more thermally conductive materials.

FIG. 7 illustrates a heat transfer device in accordance with some embodiments. The device shown in FIG. 7 is similar to the device shown in FIG. 1, except that the device shown in FIG. 7 includes a heat transfer component 702. In some embodiments, the device includes the heat transfer component 702 without any thermally conductive layer (e.g., the first thermally conductive layer 104). In some embodiments, the device includes the heat transfer component 702 in addition to one or more thermally conductive layers (e.g., the first thermally conductive layer 104).

In some embodiments, the heat transfer component includes one or more of: heat pipe, vapor chamber, or thermosiphon.

In some embodiments, the device further includes a hollow tube for allowing flow of liquid or gas for heat extraction. For example, as shown in FIG. 7, the heat transfer components 702 is a hollow tube (e.g., defining a channel therein) so that liquid or gas may flow for transferring heat.

In some embodiments, the hollow tube includes aluminum, copper, polyvinyl chloride (PVC), polyethylene (PE), or polyethylene terephthalate (PET). In some embodiments, the hollow tube consists of any combination of aluminum, copper, PVC, PE, or PET.

In some embodiments, the device is mounted in an electronic device so that the first thermally conductive layer faces a heat source.

In some embodiments, the device is mounted in an electronic device so that the first insulation layer faces a heat source.

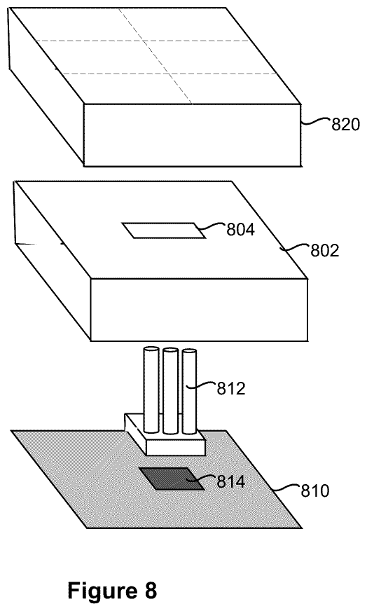

FIGS. 8-10 are exploded views showing components of devices with enclosures in accordance with some embodiments.

FIG. 8 illustrates an enclosure 802 for one or more electronic devices (e.g., a circuit board 810 with one or more electronic components thereon) in accordance with some embodiments.

In some embodiments, the enclosure 802 includes an insulation layer (e.g., the shell of the enclosure 802) that comprises aerogels and binder. In some embodiments, the enclosure 802 consists of the insulation layer.

In some embodiments, the insulation layer has a thermal conductivity of less than 30 mW/m·K at 25° C.

In some embodiments, the enclosure 802 defines one or more through-holes 804 for allowing one or more electrical cables or one or more heat transfer devices 812 to extend from outside the enclosure to inside the enclosure 802. In some embodiments, the one or more heat transfer devices 812 correspond to any of the heat transfer devices described with respect to FIGS. 1-7.

In some embodiments, the device (e.g., the device made up of all of the components shown in FIG. 8, other than the circuit board 810) also includes the one or more heat transfer devices 812. For example, the device is a combination of the enclosure 802 and the one or more heat transfer devices 812.

In some embodiments, the one or more heat transfer devices 812 include at least one heat transfer device extending vertically (e.g., the one or more heat transfer devices shown in FIG. 8).

In some embodiments, the one heat transfer device includes one or more heat pipes, liquid, or gas for heat transfer.

In some embodiments, the one or more heat transfer devices 812 are thermally coupled to the one or more electronic components (e.g., one or more electronic components located on the circuit board 810 through one or more thermal patches 814).

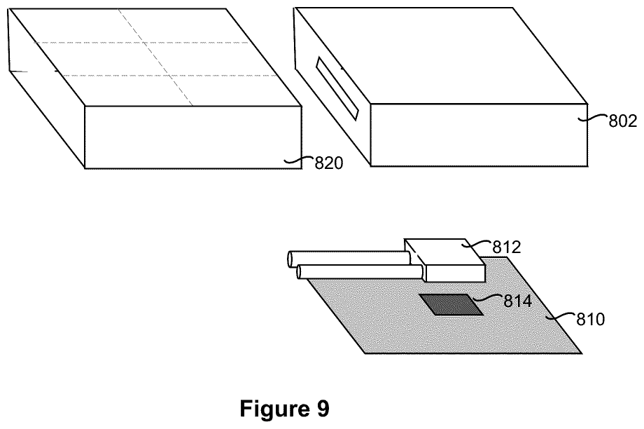

In some embodiments, the device also includes a cooling device 820 thermally coupled to the one or more heat transfer devices 812. For example, the cooling device 820 may be located above the enclosure 802 as shown in FIG. 8. Alternatively, the cooling device 820 may be located side-by-side the enclosure 802 as shown in FIG. 9.

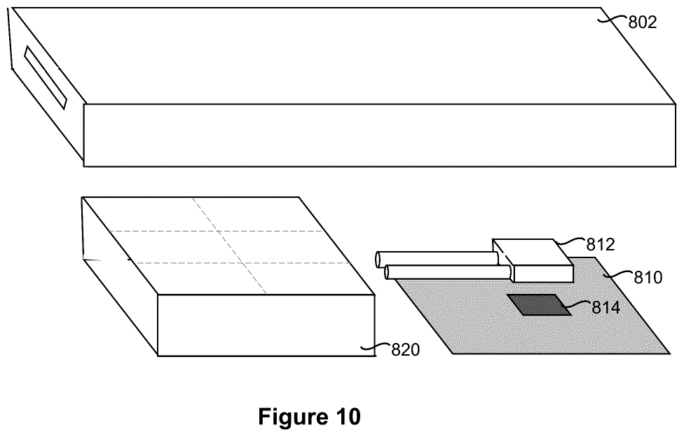

In some embodiments, the device also includes a cooling device 820 located within the enclosure 802, the cooling device 820 being thermally coupled to the one or more heat transfer devices 812. For example, the cooling device 820 shown in FIG. 10 may be inserted into the enclosure 802 (e.g., the cooling device 820 and the enclosure 802 are sized in such a way so that the cooling device 820 may be placed at least partially within the enclosure 802).

In some embodiments, the one or more heat transfer devices are configured to provide a first thermal conductivity for a first region and a second thermal conductivity for a second region that is distinct from the first region.

In some embodiments, the second thermal conductivity is distinct from the first thermal conductivity.

In some embodiments, the one or more heat transfer devices are configured to control at least one of: the first thermal conductivity or the second thermal conductivity.

In some embodiments, the cooling device is enclosed with aerogels. For example, the cooling device may be enclosed with a layer containing aerogels so that the heat enters the cooling device substantially through one or more heat transfer devices. In addition, the layer containing aerogels allow heat to be removed from the cooling device substantially through one or more heat transfer devices.

In some embodiments, the cooling device includes one or more heat pipes, liquid, or gas for heat transfer.

In some embodiments, the cooling device is located adjacent to the one or more electronic devices within the enclosure.

In some embodiments, the one or more heat transfer devices include at least one heat transfer device coupled to a low temperature source located outside the enclosure.

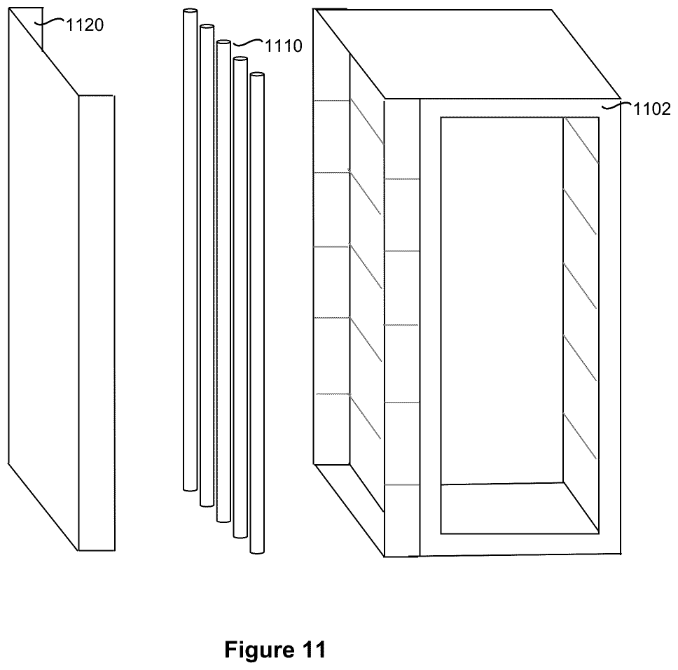

FIG. 11 illustrates a rack 1102 in accordance with some embodiments. In some embodiments, one or more devices described with respect to FIGS. 8-10 may be placed within the rack 1102. The rack 1102 also includes one or more heat transfer device 1110 (e.g., heat pipes). In some embodiments, the one or more heat transfer devices 1110 are thermally coupled to one or more cooling devices 820. This allows the one or more heat transfer devices 1110 to remove heat from the one or more cooling devices 820.

In some embodiments, the rack 1102 also includes a cover 1120. In some embodiments, the cover 1120 includes aerogels. This reduces the thermal conductivity of the cover 1120.

It will also be understood that, although the terms “first,” “second,” etc. may be used herein to describe various elements, these elements should not be limited by these terms. These terms are only used to distinguish one element from another. For example, a first layer could be termed a second layer, and, similarly, a second layer could be termed a first layer, without changing the meaning of the description, so long as all occurrences of the “first layer” are renamed consistently and all occurrences of the second layer are renamed consistently. The first layer and the second layer are both layers, but they are not the same layer, unless the context clearly indicates otherwise.

The terminology used herein is for the purpose of describing particular embodiments only and is not intended to be limiting of the claims. As used in the description of the embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the phrase “at least one of A, B and C” is to be construed to require one or more of the listed items, and this phase reads on a single instance of A alone, a single instance of B alone, or a single instance of C alone, while also encompassing combinations of the listed items such as “one or more of A and one or more of B without any of C,” and the like.

As used herein, the term “if” may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A device comprising an enclosure for one or more electronic devices, the enclosure comprising an insulation layer that comprises aerogels and binder.

2. The device of claim 1, wherein the insulation layer has a thermal conductivity of less than 30 mW/m·K at 25° C.

3. The device of claim 1, wherein the enclosure defines one or more through-holes for allowing one or more electrical cables or one or more heat transfer devices to extend from outside the enclosure to inside the enclosure.

4. The device of claim 3, further comprising the one or more heat transfer devices.

5. The device of claim 4, wherein the one or more heat transfer devices include at least one heat transfer device extending vertically.

6. The device of claim 5, wherein the one heat transfer device includes one or more heat pipes, liquid, or gas for heat transfer.

7. The device of claim 4, further comprising a cooling device located within the enclosure, the cooling device being thermally coupled to the one or more heat transfer devices.

8. The device of claim 4, wherein the one or more heat transfer devices are configured to provide a first thermal conductivity for a first region and a second thermal conductivity for a second region that is distinct from the first region.

9. The device of claim 8, wherein the second thermal conductivity is distinct from the first thermal conductivity.

10. The device of claim 8, wherein the one or more heat transfer devices are configured to control at least one of: the first thermal conductivity or the second thermal conductivity.

11. The device of claim 7, wherein the cooling device is enclosed with aerogels.

12. The device of claim 7, wherein the cooling device includes one or more heat pipes, liquid, or gas for heat transfer.

13. The device of claim 7, wherein the cooling device is located adjacent to the one or more electronic devices within the enclosure.

14. The device of claim 4, wherein the one or more heat transfer devices include at least one heat transfer device coupled to a low temperature source located outside the enclosure.
